(19) United States
(12) Patent Application Publication
(10) Pub. No.: US 2026/0139379 A1
(43) Pub. Date: May 21, 2026

(54) SUBSTRATE INCLUDING NANOWIRES

(71) Applicants: CENTRE NATIONAL DE LA RECHERCHE SCIENTIFIQUE, Paris (FR); UNIVERSITE DE LILLE, Lille (FR); NANTES UNIVERSITÉ, Nantes (FR); UNIVERSITE POLYTECHNIQUE HAUTS-DE-FRANCE, Aulnoy-Lez-Valenciennes (FR); CENTRALE LILLE INSTITUT, Villeneuve-D'Ascq (FR)

(72) Inventors: Maxime HALLOT, Denain (FR); Kévin ROBERT, Roncq (FR); Florent MARLEC, Acigne (FR); Bouchra ASBANI, Tourcoing (FR); Christophe LETHIEN, Violaines (FR); Pascal ROUSSEL, Lille (FR); Botayna BOUNOR, Toulouse (FR)

(21) Appl. No.: 19/119,286

(22) PCT Filed: Oct. 10, 2023
(86) PCT No.: PCT/FR2023/051574

§ 371 Date: Apr. 8, 2025

(30) Foreign Application Priority Data
Oct. 11, 2022 (FR) FR2210427

(51) Int. Cl. C23C 16/56; C23C 16/06; C23C 16/40

(52) U.S. Cl. CPC C23C 16/56; C23C 16/06; C23C 16/40

(57) ABSTRACT

Microstructured substrate including a main body and a plurality of elongated-shaped elementary microstructures extending from the main body, the microstructured substrate includes a plurality of nanowires positioned on at least one zone of the surface of the main body and on the surface of the elementary microstructures extending from the main body on said zone.

The present invention relates to the field of micro energy storage devices, and relates more particularly, but not exclusively, to planar and/or microstructured substrates integrating on their surface substructures of dimensions measurable on a nanometric scale. The present invention also relates to the method for manufacturing said substructures.

The bibliographical references in the following text are noted in this way in the text of the description: [ ]; and listed in the table of references.

### PRIOR ART

Substrates used in the manufacture of energy storage devices are, for example, made from supports made of semiconductor or dielectric materials and may be in the form of a thin disc, also referred to as a “wafer”. Initially, such a support has a planar surface corresponding to a two-dimensional, 2D, topology. However, depending on the intended use of the substrate, it is advantageous to hollow out the surface of the substrate on a microscale or nanoscale so that it has a three-dimensional, 3D, topology, thus defining a microstructured or nanostructured substrate.

Such a microstructured substrate has a greater usable surface area, i.e. developed surface area, than a planar (or smooth) substrate, a microstructured substrate allows for example the deposition of a greater amount of materials on its surface and more particularly on the lateral surfaces of the microstructures, which can for example improve the performance of an electrical energy storage device, increase the number of components that can be integrated on a substrate, etc.

Microstructured silicon substrates having a surface area gain linked with their rough structure are described, such as for example in patent application [1]. Such a microstructured structure is generally achieved with a surface treatment such as chemical or physical etching, microstructure growth, or electrolytic deposition of materials inside micrometric, or even nanometric, moulds, followed by dissolution of the mould.

Energy storage devices do not escape the constant need to miniaturise electronic components and there is an ongoing need to develop solutions making it possible to increase the usable surface area visible outside the substrates while retaining the dimensions of the original support from which the substrate is made; especially as it has been established that increasing the usable surface area improves the performance of solid-state microbatteries, micro-capacitors or micro-supercapacitors.

To meet this need, a first objective of the present invention consists of modifying the surface of a microstructured or nanostructured substrate to increase its usable surface area.

Furthermore, it is known to use methods for forming thin layers of materials on substrates, for example methods for producing layers of lithium-containing materials. These layered substrates are particularly used in batteries, for example for the formation of electrodes or electrolytic barriers, or any other electrical storage device. These layers can be deposited with an atomic layer deposition (commonly known as the acronym ALD) technique using precursors, with a chemical vapour layer deposition (commonly known as the acronym ALCVD) technique, or with an atomic layer epitaxy (commonly known as the acronym ALE) deposition technique. In particular, the ALD technique is a thin-film deposition technique based on gas-surface reactions in order to expose the surface whereon it is sought to deposit a layer of a material with different successive chemical precursors.

Patent application [2] describes a method implementing an atomic layer deposition of a precursor of a first metal, where such a precursor may be an organometallic complex comprising for example a transition metal (nickel, etc.) or another kind of metal such as aluminium; said method making it possible to manufacture a compound containing thin layers of lithium-containing material. Such layers have thicknesses of 1 nm to 1 μm, consisting of complex, electrochemically active materials, and which are, inter alia, homogeneous and adapted to conform to the more or less complex surface reliefs of a microstructured substrate.

A second objective of the present invention consists of modifying the surface of a substrate to increase its usable surface area by implementing such layer deposition methods compatible with microstructured substrates, the surface whereof is complex and is difficult to access with any surface treatment methods according to the prior art.

Patent application [3] describes a composite substrate consisting of a glass layer coated with a metallic layer typically of Molybdenum (Mo), indium (In) micro-pillars perpendicular to the surface of the substrate and the top part whereof is convex, a copper (Cu) layer covering said convex top part of these micro-pillars with In and copper sulphide nanowires (I) (Cu₂S) starting only from the top part of the micro-pillars.

### DESCRIPTION OF THE INVENTION

The present invention relates to a microstructured substrate comprising a main body and a plurality of elongated-shaped elementary microstructures extending from the main body, characterised in that the microstructured substrate comprises a plurality of nanowires positioned on at least one zone of the surface of the main body and on the surface of the elementary microstructures extending from the main body on said zone. Such a configuration of the substrate integrating the nanowires makes it possible to further increase the developed surface area by at least a factor of 10, and thus improve the storage capacity of a storage device integrating said substrate.

Within the scope of the present invention, the term “microstructured” or “microstructure” applies indifferently to surfaces having reliefs, the shapes whereof have dimensions that are measurable both on a microscale and on a nanoscale.

Preferably, the elongated-shaped elementary microstructures are micro-pillars or micro-tubes (which are micro-pillars hollowed out at their centres).

The main body and the elementary microstructures extending along said main body of the microstructured substrate according to the invention are advantageously made of the same material, preferably a material selected from materials comprising, or composed exclusively of, silicon Si, silicon dioxide SiO₂, gallium arsenide GaAs, silicon nitride Si₃N₄ and indium phosphide InP.

Preferably, the elementary microstructures include a cross-section selected from a circular, elliptical, rectangular, square and triangular cross-section.

Preferably, the nanowires comprise a material selected from oxides, preferably selected from SiO₂, ZnO and TiO₂, and preferably the nanowires are exclusively composed of SiO₂.

Preferably, the nanowires have a cross-section of 20 to 250 nm in diameter, and a length of 100 nm to 10 μm. Advantageously, the nanowires have a cross-section of 50 to 200 nm in diameter, and a length of 0.5 to 2 μm. The structure of these nanowires is characterised by an electron microscopy technique and more particularly by scanning electron microscopy (SEM), and the evaluation of the dimensions and structures of the nanowires is carried out using the images collected by this technique.

Preferably, the zone including nanowires has a developed surface area of 2 to 50 times the developed surface area of said zone devoid of nanowires, and advantageously 10 to 40 times, or even 15 to 35 times. The surface area gain associated with the presence of the nanowires is measured indirectly with an electrochemical method via the use of a capacitive, faradaic or pseudo-capacitive material, the electrochemical properties whereof are intrinsic to the developed surface area. The developed surface area is the representation of the total surface area introduced via the creation of porosities, anfractuosities through the addition of micro- and nano-objects with respect to the initial object; this is generally represented by a surface area gain which is a numerical value greater than 1 (where 1 is the representation of the surface area gain of the initial object).

The present invention also relates to a method for manufacturing a planar substrate or a microstructured substrate described hereinabove within the scope of the invention, comprising the following steps:
a—covering a planar or microstructured substrate with a thin layer of SiO₂;
b—depositing a layer of a non-oxidised metal with an atomic layer deposition technique;
c—performing an optical lithography step on at least one zone of the surface of the planar or microstructured support having undergone steps a- and b-;
d—performing an etching treatment; and
e—performing thermal annealing, preferably by implementing at least one temperature stage.

Step a—advantageously comprises a deposition of a nanometric thin film of SiO₂ by low-pressure chemical vapour deposition, also known as the acronym “LP CVD”.

Step b—comprises an atomic layer deposition, also known as the acronym “ALD”. The layers deposited by such an atomic layer deposition technique are deposited using precursors, as described in reference [2], with an atomic layer chemical deposition technique (commonly known as the acronym “ALCVD”), or with an atomic layer epitaxy deposition technique (commonly known as the acronym “ALE”). In particular, the ALD technique is a thin-film deposition technique based on gas-surface reactions in order to expose the surface whereon it is sought to deposit a layer of a material with different successive chemical precursors.

Step c—of optical lithography in order to limit the growth of SiO₂ nanowires only on the zones of the substrate whereon the presence of nanowires is sought. Such a step allows the formation of a resin mask which protects these zones of interest of the substrate whereon the presence of nanowires is sought, and which are zones of interest of a few mm², and leaves the material from the precursor (catalyst) “bare” on the rest of the surface of the substrate.

Step d—of dry etching the catalyst in order to retain it only on the zones of interest is advantageously carried out with reactive thermal etching, also known as the acronym “RIE”, preferably, the RIE etching is an etching implementing an RIE-ICP device marketed as a reactor by Sentech®, for example an apparatus known under the reference Sentech Si500 (ICP-RIE). Such dry etching is based on generating a reactive plasma based on a gaseous mixture of Cl₂/Ar (10 sccm, 30 sccm) in a reactor at a pressure of 5 m Torr, preferably at 10° C.

Step e—is advantageously an annealing implementing a vapour-liquid-solid synthesis technique, also known as the acronym “VLS”; such a technique has the advantage of not requiring the use of a gas-phase silane precursor as conventionally known in the literature. The growth is directly correlated, on one hand, with the change to the gas phase of the thin layer of SiO₂ generated in step a- and, on the other, with the presence of the catalyst generated in step b-. Advantageously, step e—comprises at least two stages: the first stage allowing the formation of the metal clusters in order to control the diameter of the future nanowires; the second stage making it possible to trigger the nanowire growth phenomenon.

Preferably, the non-oxidised metal deposited in step b—is selected from Pt, Ag, Au, Ga, In, Ti, Sn, Zn, Sb, Cu, Ni, Be, Fe, Co, Cr, Al, Ru, Rh and Pd, preferably it consists of Pt. It should be noted that the precursor of the first metal can be in liquid or powder form. For example, the precursor of the first metal can be chosen from the following precursors: MeCpPtMe₃, FeCl₂, FeCp₂, Fe(thd)₃, La(thd)₃, CoCp₂, MnCp₂, Mn(thd)₃, NiCp₂, TiCl₄, NbOEt₅, Cr(OCl)₂, preferably it consists of MeCpPtMe₃.

Preferably, step e—comprises two temperature stages: a first stage of 200 to 1200° C. applied for less than 5 min; and a second stage of 300 to 1400° C. applied for less than 15 min.

The present invention also relates to a use of a microstructured substrate as described above within the scope of the invention for the manufacture of a micro energy storage device, preferably selected from batteries, supercapacitors and dielectric and electrolytic capacitors of micrometric, or even nanometric size, energy recovery components or a sensor type device requiring the use of a large specific surface area.

The present invention is also described in the following detailed description, using the experimental part which details some embodiments using examples, given only by way of illustration and which should not be considered as restrictive, and the figures briefly described in the following part.

### BRIEF DESCRIPTION OF THE FIGURES

FIG. 1 shows an XRR (X-Ray Reflectometry) measurement on a thin layer of NiO deposited with ALD on a silicon substrate;

FIG. 2 shows an SEM (Scanning Electron Microscopy) view following nanowire synthesis with the VLS (Vapour-Liquid-Solid mechanism) technique;

FIG. 3 shows the profile of the rapid thermal annealing (RTA) used for the growth of SiO₂ nanowires;

FIG. 4 shows XRR measurements of thin layers of Pt of 5, 10, 15, 20 nm in thickness;

FIGS. 5A to 5D show images obtained with SEM for a layer thickness of SiO₂ of 15 nm and of Pt of 10 nm

FIG. 6 shows an SEM magnification on the surface of a substrate having undergone annealing at 900° C. for 1 min;

FIG. 7 shows an SEM magnification on the surface of a substrate having undergone annealing at 950° C. for 1 min;

FIG. 8 shows an SEM magnification on the surface of a substrate having undergone annealing at 900° C. for 1 min, followed by annealing at 1050° C. for 3 min;

FIG. 9 shows an SEM magnification on the surface of a substrate having undergone annealing at 950° C. for 1 min, followed by annealing at 1100° C. for 3 min; and

FIG. 10 shows the standardised surface area capacitance as a function of the scan rate of thin layers of RuO₂ deposited on different types of substrates making it possible to estimate the effective electrochemical gains.

### EXPERIMENTAL PART

### Materials and Methods

The reagents used are marketed by STREM® Chemical and used without further purification.

### Surface Area Measurement

The surface area gain (Area Enlargement Factor, AEF) is measured indirectly with 3-electrode cell cyclic voltammetry. The electrolyte used is sulphuric acid (H₂SO₄) diluted to 0.5 M, the reference electrode is an Ag/AgCl electrode, the counter electrode is made of platinum, the working electrode corresponds to the manufactured sample covered with a thin layer of platinum (30 nm) deposited with ALD (the microstructure substrate, the hierarchical backbone). The scan rate is 50 m V/s.

### Measurement of Thicknesses of Deposited Thin Films

The thickness of the layers is measured by X-ray reflectivity (XRR), which is an interferometry technique which makes it possible to obtain quantitative information on interface roughness, density, and thickness of amorphous or non-amorphous thin layers. After a phase of alignment of the sample height and surface, the measurement is performed. Such a measurement consists of directing an X-ray beam onto the surface of a sample at a low angle of incidence theta and collecting the reflected intensity. A measurement making it possible to trace the reflected intensity as a function of the angle of incidence (2θ) is obtained, as shown in FIG. 1. The curve generally describes a plateau for 2θ<θ_{c}, where θ_{c} corresponds to the critical angle, followed by a decline comprising one or more oscillations, the period whereof is linked to the thickness of the layer via the following relation:

$${{Θ}_{m}}^{2} = {( \frac{m λ}{2 d} )}^{2} + {{θ}_{c}}^{2} \qquad equation 1$$

Where m is the order of the oscillations and Om is the corresponding angle in radian as illustrated in FIG. 1, and d is the thickness of the layer.

The slope of the oscillations makes it possible to trace the surface roughness. And the change in slope after the oscillations makes it possible to trace the layer density. X-ray reflectivity is a technique which makes it possible to measure the thickness of a thin layer (about 5 to 100 nm) accurately using equation 1 provided that the layers have low roughness, making it a technique of choice for ALD depositions carried out within the scope of this work. The X-ray reflectivity measurements were made on a SMARTLAB® rotating copper anode system from Rigaku®.

The observation of the surface topography of the samples was performed with top-view, cross-section and grazing-incidence scanning electron microscopy (SEM) using an FEI Magellan 400™.

The nanowire size distribution is carried out with SEM and the nanowire size measurements are made with ImageJ™ software.

Within the scope of the invention, a mass percentage expressed in % w/w, defines the mass percentage of an ingredient used in the preparation and considered with respect to the total mass of the considered object: a mixture, a material (composite, etc.), a membrane, etc.

### Examples

### Part 1: Synthesis of a Silicon Oxide SiO₂ by Dry Oxidation (LP CVD, Low Pressure Chemical Vapour Deposition)

Wafer cleaning: piranha (mixture of sulphuric acid H₂SO₄ and hydrogen peroxide H₂O₂) 1:1 (20 min), deionized water rinse N₂ drying, HF 1% (2 min), EDI rinse, N₂ drying;
Introduction of the silicon wafer into the furnace at 500° C., at 2 slm (standard litres per minute, at T=0° C. and P=1 bar) of N2;
Temperature rise to 675° C. for 30 min (10° C./min);
Temperature rise to 900° C. for 1 h (10° C./min);
Pre-oxidation at 900° C. for 30 min, with 2 slm of N₂ and 0.2 slm of O₂;
Oxidation at 900° C. for 42 min (15 nm of SiO₂-deposition rate 0.357 nm/min), with 2 slm of O₂;
Temperature drop to 500° C. for 1 h, with 2 slm of N₂.

### Part 2: Atomic Layer Deposition (ALD) of a Pt Catalyst

A platinum layer is deposited with ALD, the reagents are “Pt” and dioxygen.

The sample obtained in Part 1 is placed in the ALD chamber (Beneq model TFS200), the pressure is lowered to 2 mBar and the temperature is adjusted to 300° C.

To form an atomic monolayer, different steps (corresponding to a cycle) are necessary: nitrogen is injected for 500 ms into the source containing a first reagent (1) which is MeCpPtMe₃, i.e. (trimethyl)methylcyclopentadienylplatinum(IV), declared 99% pure from STREM® Chemical), the temperature whereof is maintained at 54° C., a waiting time of 100 ms is observed in order to raise the pressure of the precursor chamber, then the source is opened for a duration of 500 ms (pulse time). A 2-second purge is then performed to expel excess species and reaction products. A second reagent (2) in the form of gaseous O₂ is then injected for a duration of 500 ms and then a 1-second purge is performed. The deposition rate is 0.83 Å/cy (Angstrom per cycle) and allows precise control of the deposited thickness from 5 to 60 nm.

### Part 3: Optical Lithography in Order to Select Zones of Interest

### 1—Wafer Cleaning and Deoxidation:

The wafer obtained in part 2 is placed in a beaker of acetone for 5 min then in isopropanol for 5 min, making it possible to degrease the wafer. The wafer is then dried at 110° C. for 10 minutes.

### 2—Resin Coating and Exposure:

Coating with an HMDS adhesion promoter (speed=2000 revolutions per minute (rpm); acceleration=1000 revolutions per minute per second (rpm/s); time=20 s).

Coating with AZ1505 resin (speed=3000 revolutions per minute; acceleration=1000 revolutions per minute per second; time=20 s).

Annealing for 1 min at 110° C., no relaxation time.

Exposure for 3 s in hard contact mode, no relaxation time.

Development for 50 s in MIF 726 followed by 30 s deionized water.

This optical lithography allows the formation of a resin mask which protects the zones of interest of a few mm² and leaves the platinum “bare” on the whole substrate.

### Part 4: Dry Etching of the Catalyst to Retain it Only on the Zones of Interest

Platinum etching is performed by RIE-ICP (Sentech®), this physico-chemical dry etching is enabled by physical Cl₂/Ar plasma etching (10 sccm, 30 sccm) in a reactor at a pressure of 5 m Torr and a temperature of 10° C. The ICP source generates a high-density plasma thanks to inductive coupling between the RF antenna and the plasma. The RF antenna creates an alternating RF magnetic field and induces RF electric fields which accelerate the electrons involved in gas molecule ionisation. To perform platinum etching, the source power is set to 600 W whereas that of the RF generator is set to 200 W. The etching rate is 2.8 Å/s. (Angström per second, i.e. 10⁻¹⁰ metres per second: this is the rate at which platinum is etched to be structured).

### Part 5: Rapid Thermal Annealing (RTA)

Annealing is performed by observing two stages in a nitrogen atmosphere in a Flash annealing furnace marketed by Jipelec®.

The synthesis technique implemented is described as vapour-liquid-solid (VLS). A first stage at 1000° C. (10° C./sec) is maintained for 1 min to dewet the Pt catalyst, during which step small clusters of Pt, which are droplets of a few tens of nanometres in diameter, are formed on the surface of the SiO₂ and form SiO in vapour phase. SiO diffuses in the droplets and precipitates at the metal/substrate interface during a second supersaturation/precipitation phase. This results in SiO₂ nanowire growth. The growth is directly correlated with the transition to the gas phase of the SiO₂ layer previously synthesised on the substrate in Part 1 and with the presence of the catalyst (here platinum).

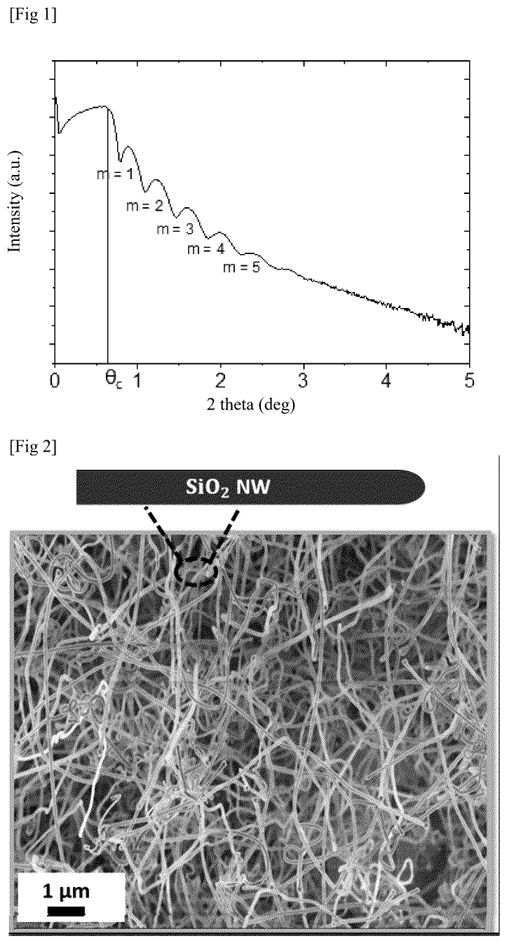

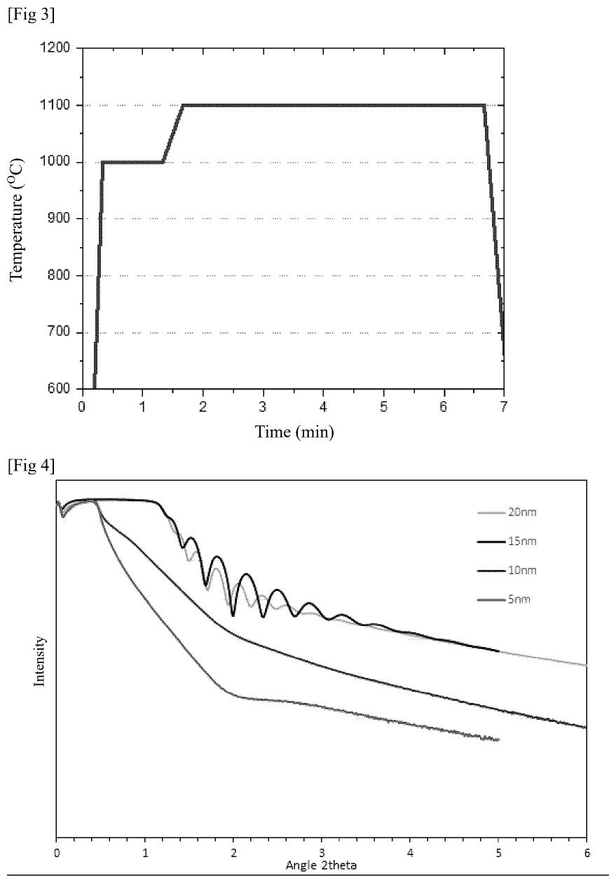

A second stage at 1100° C. is maintained for 5 min in order to promote the growth of the SiO₂ nanowires. The diameter, the length, the density (number of nanowires per mm²) of the SiO₂ nanowires are controlled by the properties of the initial thin films of SiO₂ and Pt as well as by the annealing parameters (holding temperature and time of the high-temperature stages, the first stage allowing the formation of Pt clusters in order to control the diameter of the future nanowires; and the second stage in order to induce the growth phenomenon by controlling the nanowire length). An image obtained by SEM magnification is shown in FIG. 2, with a scale to observe the dimensions of the nanowires. FIG. 3 shows the temperature profile of the stages as a function of time.

### Analyses and Results

Different silicon samples were treated after thermal annealing by checking different thickness parameters of the SiO₂ thin layer and Pt layer (5, 10, 15, 20 nm). The Pt thin layers were measured with XRR, the diagrams are shown in FIG. 4.

The samples are observed with SEM microscopy.

By varying the thickness of SiO₂ from 10 to 15 nm, the inventors observed the presence of very solid matchstick-shaped nanowires which are strictly perpendicular to the surface with a mean length greater than 1 μm and a diameter that may be greater than 80 nm.

A statistical study of the SEM images makes it possible to determine the mean nanowire diameter and length parameters. The general method consists of analysing images through processing making it possible to delineate the boundaries of the constituent objects. An analysis of the image then makes it possible to count, pixel by pixel, the space occupied by each object (length, diameter, intersections with other objects, surface areas, etc.).

The results are shown in Table 2 for a Pt layer thickness of 15 nm:

TABLE 2

| SiO₂ layer | Mean | Mean |
|---|---|---|
| thickness | Diameter | Length |
| (nm) | (nm) | (μm) |
| 5 | 30-47 | 12-20 |
| 10 | 33-53 | 15-20 |
| 15 | 32-70 | 2-3 |
| 20 | 47-75 | 1-3 |

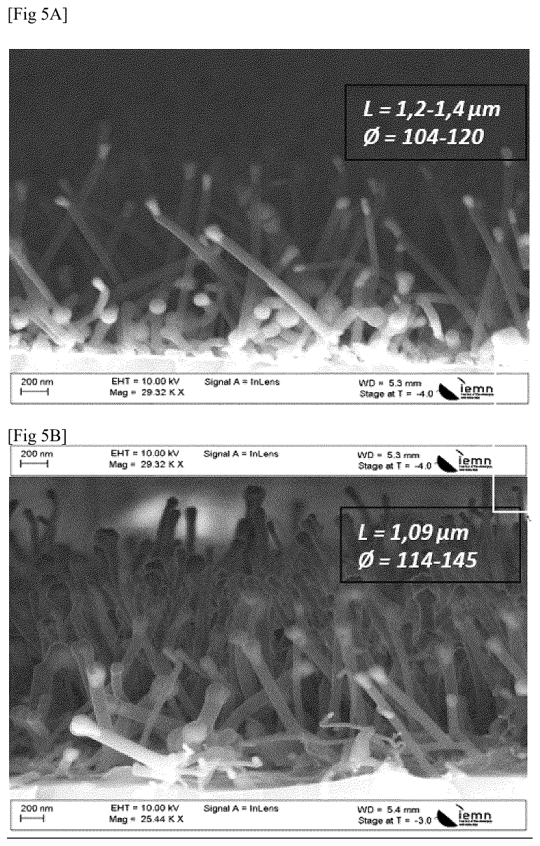

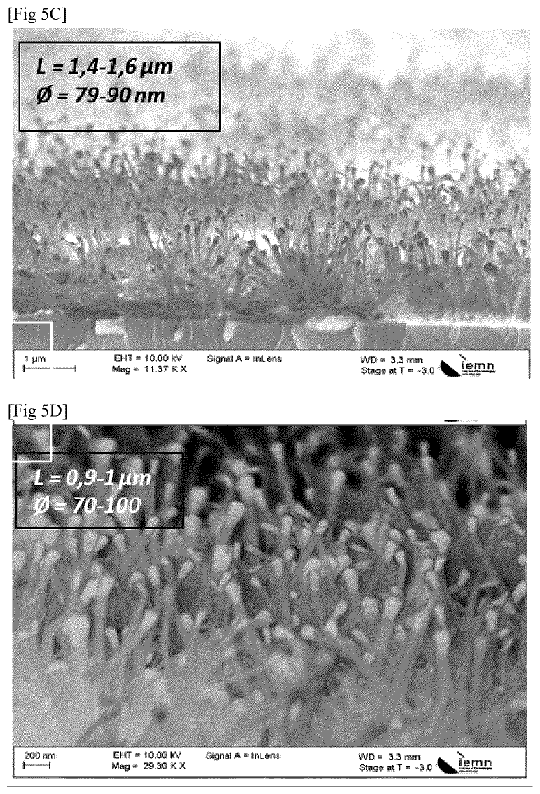

Other results are shown in Table 3 for a layer thickness of SiO₂ of 15 nm and of Pt of 10 nm, and the images obtained are shown in FIGS. 5A-5D:

TABLE 3

| | Mean | Mean |
|---|---|---|
| Sample | Diameter | Length |
| number | (nm) | (μm) |
| 1 | 70-100 | 0.9-1 |
| 2 | 79-90 | 1.4-1.6 |
| 3 | 104-120 | 1.2-1.4 |
| 4 | 114-145 | 1.09 |

### Study of Temperature Stage-Related Phenomena:

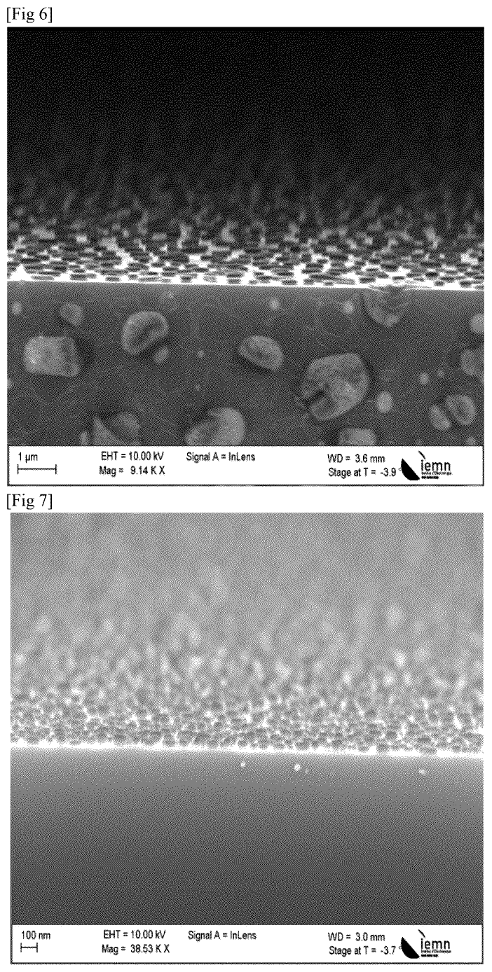

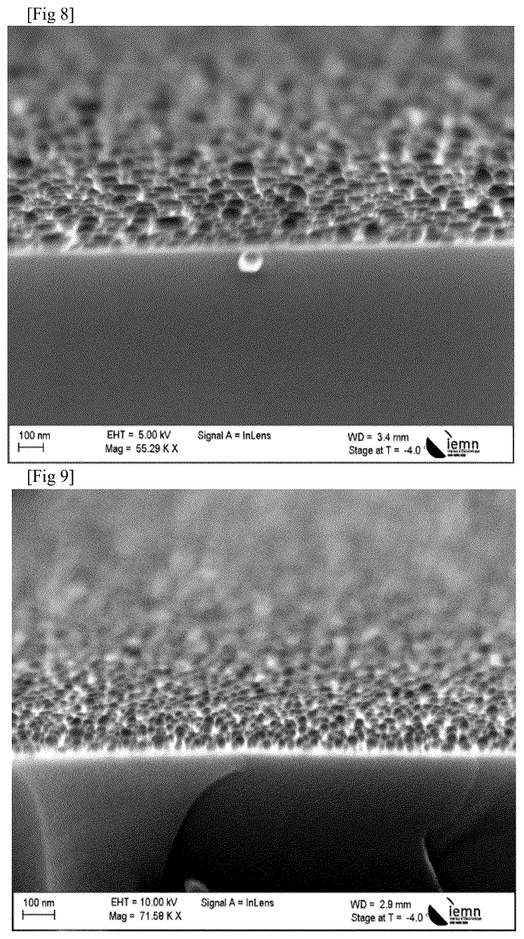

the role of the two annealing stages was determined thanks to SEM images. The first allows Platinum dewetting via the formation of Pt droplets on the surface under which the evaporated SiO₂ condenses during the second temperature stage:
FIG. 6 corresponds to a substrate having undergone annealing at 900° C. for 1 min;
FIG. 7 corresponds to a substrate having undergone annealing at 950° C. for 1 min;
FIG. 8 corresponds to a substrate having undergone annealing at 900° C. for 1 min, then at 1050° C. for 3 min;
FIG. 9 corresponds to a substrate having undergone annealing at 950° C. for 1 min, then at 1100° C. for 3 min.

FIGS. 6 to 8 show the importance of the first stage for promoting catalyst (Pt) dewetting for nanowire growth. FIG. 8 shows in particular that the first stage at 900° C. is insufficient to promote growth during the second stage. FIG. 9 shows that a first stage at 950° C. followed by a second step at 1100° C. makes it possible to obtain initial growth. This FIG. 9 also shows the importance of the duration of the second stage on the nanowire length which is applied here for a duration of 3 min (whereas for the other results described in the present experimental part, the second stage is applied for 5 min).

### Measurement of the Surface Area Gain Provided by the Nanowires:

The inventors demonstrated that the high surface area capacitance of the components integrating the substrates according to the invention was closely linked with their structure, and even when said structure includes an infinity of complex structural elements in terms of material architecture, or even substantially entangled with each other. The high surface area capacitance is from a large surface area expressed with respect to the projected surface area, this being provided by the presence of micropillars (microstructured substrate) covered by nanowires. The methodology adopted to determine the surface area gain consists of using a parameter referred to as the “Area Enlargement Factor”, also known as “AEF”, and comparing the AEF of the different structures and the contribution of each, the AEFs being measured independently, first on a planar surface in 2D, then in 3D and 2D with nanowires and 3D with nanowires.

The different measurements were made under the same conditions to calculate the surface area gain (AEF) measured with 3-electrode cell cyclic voltammetry. The electrolyte used is sulphuric acid (H₂SO₄) diluted to 0.5M, the reference electrode is an Ag/AgCl electrode, the counter electrode is made of platinum, the working electrode is platinum (30 nm) deposited with ALD on the sample to be measured (the microstructured “backbone”). The scan rate is 50 mV/s. The projected surface area viewed during measurement is 0.407 cm². The results are shown in Table 4 below:

TABLE 4

| | | Surface | |
|---|---|---|---|
| | | area | AEF |
| Samples | Area | (cm²) | Measured |
| 2D structure (reference | 0.00473 | 0.45 | 1.1 |
| planar surface) | | | |
| 3D structure - Expected | 0.03347 | 3.22 | 18.6 |
| gain 18 | | | |
| 3D structure - Expected | 0.0972 | 8.83 | 57 |
| gain 55 | | | |
| Nanowires 10 nm SiO₂ - | 0.08085 | 7.77 | 19.1 |
| 5 nm Pt | | | |
| Nanowires 10 nm SiO₂ - | 0.07281 | 7.00 | 17.2 |
| 10 nm Pt | | | |
| Nanowires 15 nm SiO₂ - | 0.01693 | 1.63 | 4.00 |
| 10 nm Pt | | | |
| Nanowires 15 nm SiO₂ - | 0.00721 | 0.63 | 1.7 |
| 20 nm Pt | | | |

Thus, Table 4 shows that the measurement method makes it possible to trace the calculated 3D gains (table entries in rows 3 and 4) from the micro-tube type 3D structures. This method demonstrates that the nanowires provide a surface area gain of 2 to 19 in the examples cited in the rest of Table 2, respectively at the entries of rows 5 to 8.

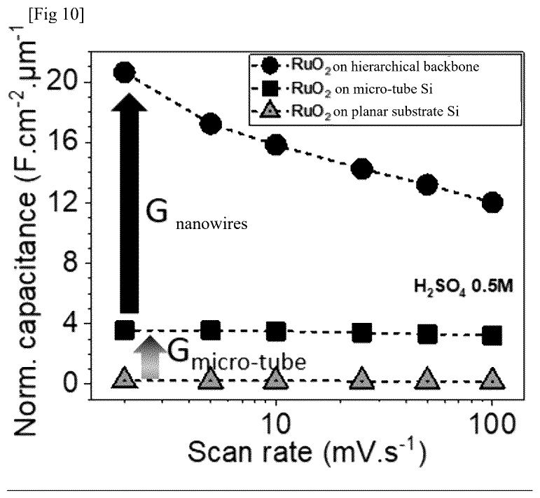

An identical measurement was made with the use of a supercapacitor electrode material (RuO₂) which shows a gain of 10 on microstructures having a gain of 50 (i.e. a total surface area gain of 50×10=500). It was thus demonstrated that the surface area gain of the microstructures is between 50 and 70, that of the nanowires between 4 and 10. FIG. 10 shows the capacitance as a function of the scan rate of thin layers of RuO₂ on different types of substrates, thus the inventors were able to demonstrate completely unexpectedly that the cumulative gains are not added but are multiplied, making it possible to achieve gains of between 200 and 700. In this FIG. 10, we find the capacitance of thin layers of RuO₂ making it possible to trace a surface area gain of 50 (squares) for a micro-tube type structure and 500 (circles) on a hierarchical substrate compared to a planar surface (triangles).

### REFERENCES

The following table lists the references mentioned above in the text:

TABLE 1

| | |
|---|---|
| 1 | WO2015/052412 |
| 2 | WO2022/069842 |
| 3 | WO2020114379 |

What is claimed is:

1. Microstructured substrate comprising a main body and a plurality of elongated-shaped elementary microstructures extending from the main body, characterised in that the microstructured substrate comprises a plurality of nanowires positioned on at least one zone of the surface of the main body and on the surface of the elementary microstructures extending from the main body on said zone.

2. Microstructured substrate according to claim 1, wherein the main body and the elementary microstructures extending along said main body are made of the same material, preferably a material selected from materials comprising, or composed exclusively of, silicon, silicon dioxide SiO₂, gallium arsenide GaAs, silicon nitride Si₃N₄ and indium phosphide InP.

3. Microstructured substrate according to claim 1, wherein the elementary microstructures include a cross-section chosen from a circular, elliptical, rectangular, square and triangular section.

4. Microstructured substrate according to claim 1, wherein the nanowires comprise a material selected from oxides, preferably selected from SiO₂, ZnO and TiO₂, and preferably the nanowires are exclusively composed of SiO₂.

5. Microstructured substrate according to claim 1, wherein the nanowires have a cross-section of 20 to 250 nm in diameter, and a length of 100 nm to 10 μm.

6. Microstructured substrate according to claim 1, wherein the zones including nanowires have a developed surface area of 2 to 50 times the developed surface area of said zone devoid of nanowires.

7. Method for manufacturing a device according to claim 1, comprising the following steps:
a—covering a planar or microstructured substrate with a thin layer of SiO₂;
b—depositing a layer of a non-oxidised metal with an atomic layer deposition technique;
c—performing optical lithography on at least one zone of the surface of the planar or microstructured support having undergone steps a- and b-;
d—performing an etching treatment; and
e—performing thermal annealing, preferably by implementing at least one temperature stage.

8. Method for manufacturing a microstructured substrate according to claim 7, wherein the non-oxidised metal deposited in step b—is selected from Pt, Ag, Au, Ga, In, Ti, Sn, Zn, Sb, Cu, Ni, Be, Fe, Co, Cr, Al, Ru, Rh and Pd, preferably it consists of Pt.

9. Method for manufacturing a microstructured substrate according to claim 8, wherein step e—comprises two temperature stages: a first stage of 200 to 1200° C. applied for less than 5 min; and a second stage of 300 to 1400° C. applied for less than 15 min.

10. A micro energy storage device comprising the microstructured substrate according to claim 1.

11. A micro energy storage device according to claim 10, wherein the devise is selected from the group consisting of batteries, supercapacitors and dielectric and electrolytic capacitors of micrometric, nanometric size, energy recovery components and a sensor-type device requiring the use of a large specific surface area.
